(19) United States
(12) Patent Application Publication
(10) Pub. No.: US 2024/0213341 A1
(43) Pub. Date: Jun. 27, 2024

(54) SEMICONDUCTOR DEVICE AND MANUFACTURING METHOD OF THE SAME

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: Hitoshi FUJIOKA, Nisshin-shi (JP)

(21) Appl. No.: 18/524,195

(22) Filed: Nov. 30, 2023

(30) Foreign Application Priority Data
Dec. 27, 2022 (JP) 2022-210136

(51) Int. Cl. H01L 29/423; H01L 29/66; H01L 29/78

(52) U.S. Cl. CPC H01L 29/4236; H01L 29/66734; H01L 29/7813

(57) ABSTRACT

A semiconductor device includes a semiconductor layer formed with trenches, and trench gates correspondingly disposed in the trenches. The trenches extend in a first direction, and are arranged spaced apart from each other in a second direction orthogonal to the first direction. The trenches include an inner trench located between end trenches in the second direction. The inner trench has end side walls opposite in the first direction, and longitudinal side walls between the end side walls. The end side walls have a surface roughness larger than that of intermediate portions of the longitudinal side walls, the intermediate portions being at an intermediate position in the first direction. An insulating film disposed in the inner trench has a larger thickness on at least one of the end side walls than on at least one of intermediate portions of the longitudinal side walls.

### CROSS REFERENCE TO RELATED APPLICATION

The present application claims the benefit of priority from Japanese Patent Application No. 2022-210136 filed on Dec. 27, 2022. The entire disclosures of the above application are incorporated herein by reference.

### TECHNICAL FIELD

The present disclosure relates to a semiconductor device and a manufacturing method of the semiconductor device.

### BACKGROUND

A semiconductor device having a plurality of trench gates has been developed. The trench gates are correspondingly provided in trenches formed in an upper layer portion of a semiconductor layer. If the side wall of the trench formed in the upper layer portion of the semiconductor layer have unevenness on its surface, the withstand voltage and reliability of a gate insulating film of the trench gate will be degraded. For example, it has been proposed a technique of removing the unevenness of the side wall of the trench by using a chemical dry etching method after the trench is formed.

### SUMMARY

The present disclosure describes a semiconductor device and a manufacturing method of the semiconductor device. According to an aspect, the semiconductor device may include a semiconductor layer formed with a plurality of trenches in a surface layer portion, and a plurality of trench gates correspondingly provided in the plurality of trenches of the semiconductor layer. Each of the plurality of trenches may extend at least in a first direction in a plan view of the semiconductor layer. The plurality of trenches may be arranged apart from each other in a second direction orthogonal to the first direction in the plan view of the semiconductor layer. Each of the plurality of trenches may have a pair of end side walls at ends in the first direction and a pair of longitudinal side walls extending between the pair of end side walls. Each of the plurality of trench gates may include a gate insulating film covering the pair of end side walls and the pair of longitudinal side walls of the trench. The plurality of trenches may include a pair of end trenches located at opposite ends in the second direction and an inner trench located between the pair of end trenches in the second direction. At least one of the end side walls of the inner trench may have a surface roughness larger than a surface roughness of at least one of intermediate portions of the longitudinal side walls of the inner trench, the intermediate portions being at an intermediate position of the inner trench in the first direction. The gate insulating film disposed in the inner trench may have a larger thickness on the at least one of the end side walls than on the at least one of the intermediate portions of the longitudinal side walls.

### BRIEF DESCRIPTION OF THE DRAWINGS

Objects, features and advantages of the present disclosure will become more apparent from the following detailed description made with reference to the accompanying drawings, in which like parts are designated by like reference numbers and in which:

FIG. 1 is a plan view of a semiconductor layer of a semiconductor device for showing a layout of a plurality of trenches according to a first embodiment of the present disclosure;

FIG. 2 is a schematic perspective view of a vicinity of an end of a trench at an upper layer portion of the semiconductor layer;

FIG. 3 is a schematic cross-sectional view of a part of a semiconductor device taken along a line III-III in FIG. 1 according to the first embodiment;

FIG. 4 is a schematic cross-sectional view of a part of the semiconductor device taken along a line IV-IV in FIG. 1 according to the first embodiment;

FIG. 5 is an electron micrograph of a longitudinal side wall of an end trench according to the first embodiment;

FIG. 6 is an electron micrograph of a longitudinal side wall of an inner trench according to the first embodiment;

FIG. 7 is a flowchart showing a process for forming a trench gate in a manufacturing process of the semiconductor device according to the first embodiment;

FIG. 8 is a cross-sectional view of parts of the semiconductor layer during the process for forming the trench gate according to the first embodiment;

FIG. 9 is a cross-sectional view of the parts of the semiconductor layer during the process for forming the trench gate according to the first embodiment;

FIG. 10 is a cross-sectional view of the parts of the semiconductor layer during the process for forming the trench gate according to the first embodiment;

FIG. 11 is a cross-sectional view of the parts of the semiconductor layer during the process for forming the trench gate according to the first embodiment;

FIG. 12 is a schematic cross-sectional view of a part of the semiconductor device, corresponding to the section taken along the line III-III in FIG. 1, according to a second embodiment of the present disclosure;

FIG. 13 is a schematic cross-sectional view of a part of the semiconductor device, corresponding to the section taken along the line IV-IV in FIG. 1, according to the second embodiment;

FIG. 14 is a cross-sectional view of parts of a semiconductor layer of the semiconductor device during a process for forming a trench gate in a manufacturing process of the semiconductor device according to the second embodiment;

FIG. 15 is a cross-sectional view of the parts of the semiconductor layer during the process for forming the trench gate in the manufacturing process of the semiconductor device according to the second embodiment;

FIG. 16 is a cross-sectional view of the parts of the semiconductor layer during the process for forming the trench gate in the manufacturing process of the semiconductor device according to the second embodiment;

FIG. 17 is a cross-sectional view of the parts of the semiconductor layer during the process for forming the trench gate in the manufacturing process of the semiconductor device according to the second embodiment;

FIG. 18 is a schematic plan view of an end of a trench of a semiconductor device according to an example of a third embodiment of the present disclosure;

FIG. 19 is a schematic plan view of an end of a trench of the semiconductor device according to another example of the third embodiment; and

FIG. 20 is a schematic plan view of an end of a trench of the semiconductor device according to further another example of the third embodiment.

### DETAILED DESCRIPTION

To begin with, a relevant technology will be described only for understanding the embodiments of the present disclosure.

In a semiconductor device having a plurality of trench gates, the trench gates are correspondingly provided in trenches formed in an upper layer portion of a semiconductor layer. In such a semiconductor device, if the side wall of the trench have unevenness on its surface, the withstand voltage and reliability of a gate insulating film disposed on the side wall of the trench will be degraded. As a countermeasure, it has been proposed to remove the unevenness of the side wall of the trench by using a chemical dry etching method after the trench is formed.

When the unevenness of the side wall of the trench is sufficiently removed, the etching amount increases. As a result, the width of the trench increases, and the distance between adjacent trenches decreases. It is thus conceivable to increase the trench pitch in order to secure the distance between the adjacent trenches while sufficiently removing the unevenness of the side walls of the trenches. In such a case, however, the miniaturization of the semiconductor device is sacrificed. The present disclosure provides a technique useful for the miniaturization of the semiconductor device having a plurality of trench gates.

According to an aspect of the present disclosure, the semiconductor device may include a semiconductor layer formed with a plurality of trenches in a surface layer portion, and a plurality of trench gates correspondingly provided in the plurality of trenches of the semiconductor layer. Each of the plurality of trenches may extend at least in a first direction in a plan view of the semiconductor layer. The plurality of trenches may be arranged apart from each other in a second direction orthogonal to the first direction in the plan view of the semiconductor layer. Each of the plurality of trenches may have a pair of end side walls at ends in the first direction and a pair of longitudinal side walls extending between the pair of end side walls. Each of the plurality of trench gates may include a gate insulating film covering the pair of end side walls and the pair of longitudinal side walls of the trench. The plurality of trenches may include a pair of end trenches located at opposite ends in the second direction and an inner trench located between the pair of end trenches in the second direction. At least one of the end side walls of the inner trench may have a surface roughness larger than a surface roughness of at least one of intermediate portions of the longitudinal side walls of the inner trench, the at least one of the intermediate portions being at an intermediate position of the inner trench in the first direction. The gate insulating film disposed in the inner trench may have a larger thickness on at least one of the end side walls than on the at least one of the intermediate portions of the longitudinal side walls.

In such a semiconductor device, the thickness of the gate insulating film is larger on the side wall of the trench having a larger surface roughness. Therefore, the deterioration of the breakdown voltage and reliability of the gate insulating film due to the unevenness of the side wall of the trench is suppressed. In other words, in the semiconductor device described above, the deterioration of the breakdown voltage and reliability of the gate insulating film is suppressed while allowing the unevenness of the side wall of the trench. In the semiconductor device described above, since it is not necessary to sufficiently remove the unevenness of the side wall of the trench, it is possible to make the trench pitch small. As such, the semiconductor device has a structure useful for the miniaturization.

According to an aspect of the present disclosure, a manufacturing method of a semiconductor device may include: forming a plurality of trenches in an upper layer portion of a semiconductor layer; and forming a plurality of trench gates correspondingly in the plurality of trenches. In the forming of the plurality of trenches, each of the plurality of trenches may be formed to extend at least in a first direction in a plan view of the semiconductor layer, and to have a pair of end side walls at opposite ends in the first direction and a pair of longitudinal side walls extending between the end side walls. Also, the plurality of trenches may be formed to be arranged spaced apart from each other in a second direction orthogonal to the first direction in the plan view of the semiconductor layer, and to include a pair of end trenches located at opposite ends in the second direction and an inner trench located between the pair of end trenches in the second direction. The forming of the plurality of trench gates may include forming a gate insulating film in the inner trench so that a thickness of the gate insulating film on at least one of the end side walls of the inner trench is larger than a thickness of the gate insulating film on at least one of intermediate portions of the longitudinal side walls of the inner trench, the intermediate portion being at an intermediate position of the inner trench in the first direction, in a state where the at least one of the end side walls of the inner trench has a surface roughness larger than a surface roughness of the at least one of the intermediate portions of the longitudinal side walls of the inner trench.

In such a method, the thickness of the gate insulating film is larger on the side wall of the trench having a larger surface roughness. Therefore, in the semiconductor device manufactured by the manufacturing method described above, the deterioration of the breakdown voltage and reliability of the gate insulating film due to the unevenness of the side wall of the trench is suppressed. In other words, in the manufacturing method described above, the deterioration of the breakdown voltage and reliability of the gate insulating film can be suppressed while allowing the unevenness on the side wall of the trench. In the manufacturing method described above, since it is not necessary to sufficiently remove the unevenness of the side wall of the trench, it is possible to manufacture the semiconductor device having a smaller trench pitch. As such, the manufacturing method described above can produce the semiconductor device having fine structures.

Hereinafter, semiconductor devices according to multiple embodiments of the present disclosure will be described with reference to the drawings. Components common in the multiple embodiment are denoted by the reference numerals, and description thereof will not be repeated. For components that are repeatedly arranged, the reference numeral will be indicated on only one of the components for the sake of clarity of illustration.

### First Embodiment

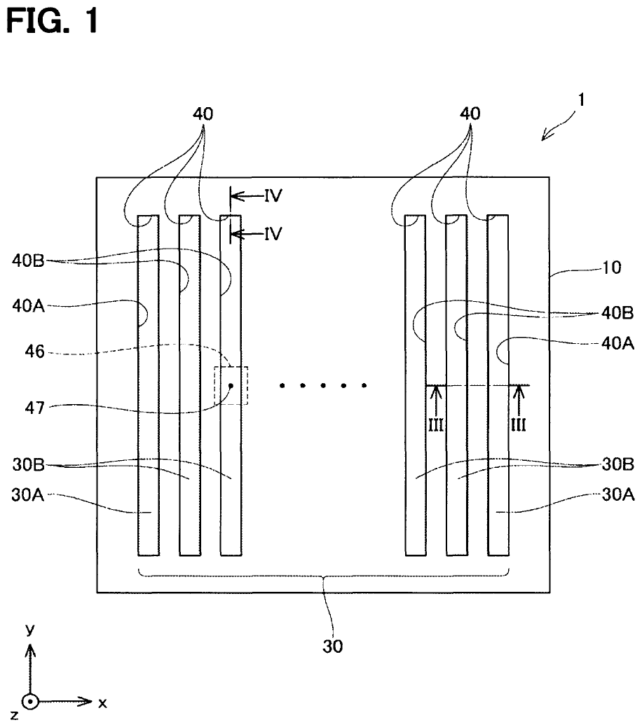

As shown in FIG. 1, a semiconductor device 1 includes a semiconductor layer 10. The semiconductor layer 10 is not particularly limited, but may be a 4H silicon carbide layer, for example. The crystal plane on an upper surface of the semiconductor layer 10 may be inclined by an off angle with respect to the (0001) Si plane. The off angle is not particularly limited, but may be 4°, for example. In place of the silicon carbide layer, the semiconductor layer 10 may be a silicon layer, a nitride semiconductor layer, or a gallium oxide layer, for example. Hereinafter, a thickness direction of the semiconductor layer 10 will be referred to as a z direction, one direction parallel to the upper surface of the semiconductor layer 10 will be referred to as an x direction, and a direction orthogonal to the x direction and the z direction will be referred to as a y direction.

The semiconductor device 1 has a plurality of trench gates 30 disposed in an upper layer portion of the semiconductor layer 10. Each of the trench gates 30 extends in one direction as a longitudinal direction in a plan view of the semiconductor layer 10 when viewed in the z direction. In this example, each of the trench gates 30 extends in the y direction. Thus, the y direction corresponds to the longitudinal direction of the trench gate 30. In addition, the plurality of trench gates 30 are arranged apart from each other in a direction orthogonal to the longitudinal direction of the trench gates 30 in the plan view. In this example, the plurality of trench gates 30 are arranged apart from each other in the x direction, which is orthogonal to the longitudinal direction. Hereinafter, the x direction will be also referred to as a repetition direction of the trench gates 30. As described above, the trench gates 30 are arranged in a stripe shape in the plan view of the semiconductor layer 10. Also, the y direction corresponds to a first direction, and the x direction corresponds to a second direction.

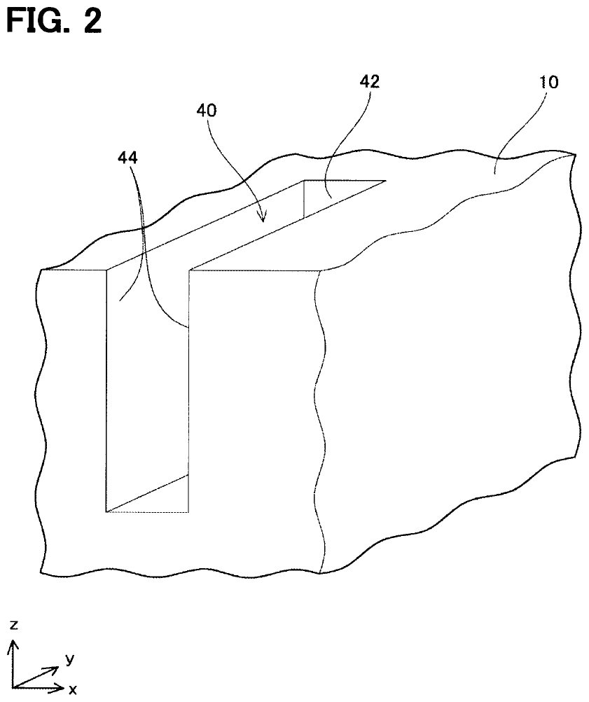

Each of the trench gates 30 is provided in a corresponding one of trenches 40 formed in the upper layer portion of the semiconductor layer 10. FIG. 2 shows the vicinity of an end portion of one trench 40 formed in the upper layer portion of the semiconductor layer 10. In the present disclosure, each trench 40 has a pair of side walls at opposite ends in the longitudinal direction, that is, in the y direction, and a pair of side walls facing in the repetition direction, that is, in the x direction. Among the side walls of the trench 40, the pair of side walls at opposite ends in the longitudinal direction, that is, in the y direction are referred to as a pair of end side walls 42. The end side walls 42 are formed to face each other in the longitudinal direction of the trench 40. Each of the end side walls 42 is a side wall that is not parallel to the longitudinal direction of the trench 40. In this example, each of the end side walls 42 extends in a direction orthogonal to the longitudinal direction of the trench 40, that is, extends parallel to a xz plane including the x direction and the z direction. Among the side walls of the trench 40, the pair of side walls extending between the pair of end side walls 42 is referred to as a pair of longitudinal side walls 44. Each of the longitudinal side walls 44 is a side wall parallel to the longitudinal direction of the trench 40. In this example, each of the longitudinal side walls extends parallel to a yz plane including the y direction and the z direction.

As shown in FIG. 1, among the trench gates 30, the trench gates 30 disposed at opposite ends in the repetition direction are referred to as end trench gates 30A to be distinguished from the other trench gates 30. The trenches 40 for the end trench gates 30A are referred to as end trenches 40A. Among the trench gates 30, the trench gates 30 disposed between the end trench gates 30A are referred to as inner trench gates 30B to be distinguished from the end trench gates 30. The trenches 40 for the inner trench gates 30B are referred to as inner trenches 40B.

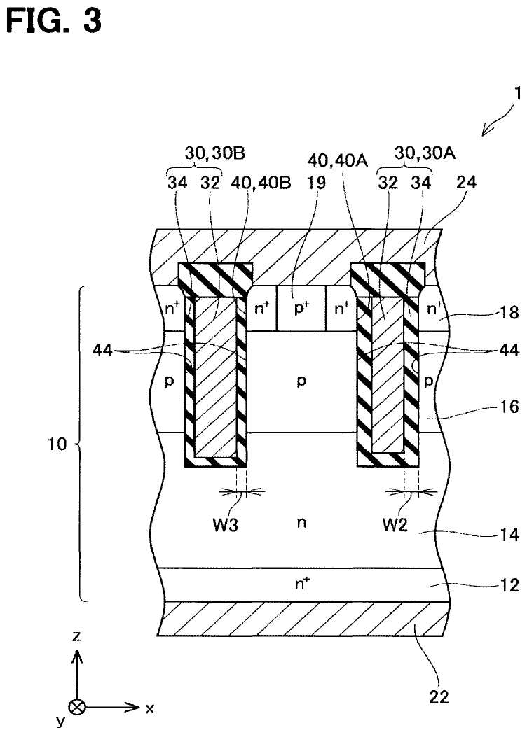

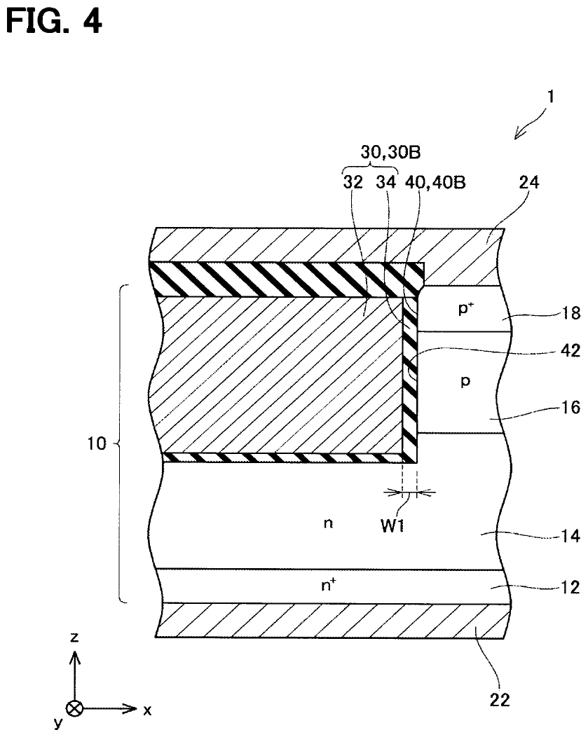

As shown in FIGS. 3 and 4, the semiconductor device 1 is a power semiconductor device of a type called a metal oxide semiconductor field effect transistor (MOSFET). The semiconductor device 1 thus includes a drain electrode 22 covering the lower surface of the semiconductor layer 10 and a source electrode 24 covering the upper surface of the semiconductor layer 10. The semiconductor layer 10 includes an n⁺-type drain region 12, an n-type drift region 14, a p-type body region 16, an n⁺-type source region 18, and a p⁺-type body contact region 19.

The drain region 12 is disposed in a lower layer portion of the semiconductor layer 10. The drain region 12 is provided at a position exposed on the lower surface of the semiconductor layer 10. The drain region 12 is in ohmic contact with the drain electrode 22 covering the lower surface of the semiconductor layer 10.

The drift region 14 is provided between the drain region 12 and the body region 16. The drift region 14 has the n-type impurity concentration lower than the n-type impurity of the drain region 12. The drift region 14 may have a super junction structure in which n-type columns and p-type columns are alternately arranged in at least one direction in a transverse section of the semiconductor layer 10.

The body region 16 is provided on the drift region 14, and is disposed in the upper layer portion of the semiconductor layer 10. The body region 16 is provided between the drift region 14 and the source region 18. The body region 16 is in contact with both the drift region 14 and the source region 18, and separates the drift region 14 and the source region 18 from each other. The p-type impurity concentration of the body region 16 is adjusted in accordance with a desired gate threshold voltage.

The source region 18 is provided on the body region 16. The source region 18 is disposed in the upper layer portion of the semiconductor layer 10. The source region 18 is provided at a position exposed on the upper surface of the semiconductor layer 10. The source region 18 is in contact with the side surface of the trench gate 30. The source region 18 is in ohmic contact with the source electrode 24 covering the upper surface of the semiconductor layer 10.

The body contact region 19 is provided on the body region 16. The body contact region 19 is disposed in the upper layer portion of the semiconductor layer 10. The body contact region 19 is provided at a position exposed on the upper surface of the semiconductor layer 10. The body contact region 19 is in ohmic contact with the source electrode 24 covering the upper surface of the semiconductor layer 10.

Each of the trench gates 30 extends from the upper surface of the semiconductor layer 10 while penetrating the source region 18 and the body region 16 and reaches the drift region 14. Each of the trench gates 30 includes a gate electrode 32 and a gate insulating film 34. Although not particularly limited, the gate electrode 32 is formed of a polysilicon containing an impurity, for example. The gate electrode 32 faces the semiconductor layer 10 across the gate insulating film 34. In particular, the gate electrode 32 faces a portion of the body region 16, which separates the drift region 14 and the source region 18 from each other, across the gate insulating film 34. Although not particularly limited, the gate insulating film 34 is formed of, for example, a high-temperature silicon oxide film (HTO film), and covers an inner wall surface of the trench 40.

Next, an operation of the semiconductor device 1 will be described. In a state where the potential of the drain electrode 22 is higher than the potential of the source electrode 24, when the potential of the gate electrode 32 of the trench gate 30 is controlled to be higher than the potential of the source electrode 24 and the potential of the threshold value, the semiconductor device 1 is turned on. At this time, an inversion layer is formed in the portion of the body region 16, which separates the source region 18 and the drift region 14, as a channel. Electrons supplied from the source region 18 reach the drift region 14 through the channel of the inversion layer. The electrons reaching the drift region 14 flow to the drain region 12 via the drift region 14. On the other hand, when the potential of the gate electrode 32 of the trench gate 30 is controlled to be the same as the potential of the source electrode 24, the channel of the inversion layer disappears, and the semiconductor device 1 is turned off. In this way, the semiconductor device 1 can operate as a switching element.

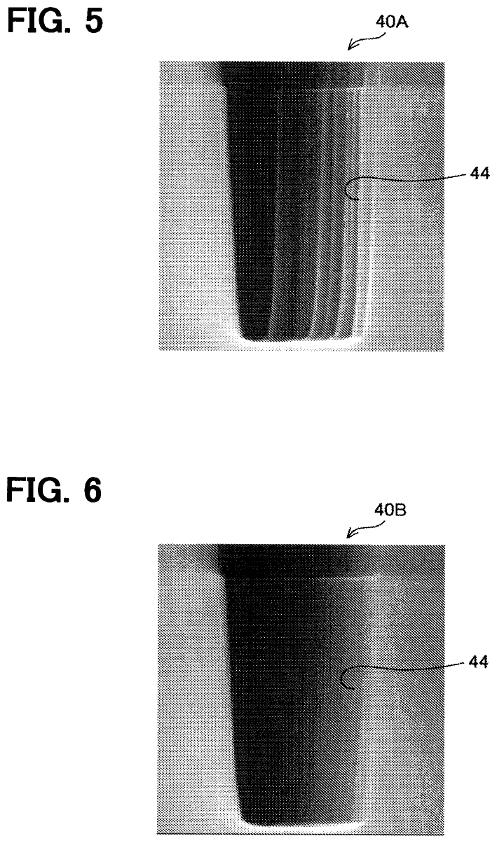

Next, features of the semiconductor device 1 will be described. FIG. 5 shows an electron micrograph of the longitudinal side wall 44 of the end trench 40A for the end trench gate 30A. FIG. 6 shows an electron micrograph of the longitudinal side wall 44 of the inner trench 40B for the inner trench gate 30B. As shown in FIG. 5, the longitudinal side wall 44 of the end trench 40A is formed with large unevenness, that is, projections and recesses defining large height differences on the wall surface. On the other hand, as shown in FIG. 6, the longitudinal side wall 44 of the inner trench 40B is formed with small unevenness, that is, projections and recesses defining small height differences on the wall surface. Alternatively, the longitudinal side wall 44 of the inner trench 40B may be substantially flat without unevenness. Therefore, as shown in FIGS. 5 and 6, the surface roughness of the longitudinal side wall 44 of the end trench 40A is larger than the surface roughness of the longitudinal side wall 44 of the inner trench 40B. Although not shown, each of the end side walls 42 of the end trench 40A and each of the end side walls 42 of the inner trench 40B are formed with the large unevenness same as the longitudinal side wall 44 of the end trench 40A. Therefore, the surface roughness of each end side wall 42 of the end trench 40A and the surface roughness of each end side wall 42 of the inner trench 40B are also larger than the surface roughness of the longitudinal side wall 44 of the inner trench 40B.

The unevenness of each surface described above is provided by the unevenness that is formed and kept on the wall surface of the trench 40 when the trench 40 is formed by an etching process in a manufacturing method described later. The magnitude of the unevenness, that is, the surface roughness depends on the positions of the trenches 40, and increases toward an outer peripheral portion in a region where the trenches 40 are formed. Therefore, the surface roughness of the end side walls 42 of the end trenches 40A and the inner trenches 40B and the surface roughness of the longitudinal side walls 44 of the end trenches 40A are larger than the surface roughness of the longitudinal side walls 44 of the inner trenches 40A. The surface roughness as used herein refers to an arithmetic average roughness (Ra).

In the present disclosure, unless otherwise specified, the longitudinal side walls 44 of the inner trench 40B refer to a pair of longitudinal side walls 44 located at an intermediate portion in the longitudinal direction (in this example, the y direction) of the inner trench 40B. As shown in FIG. 1, the intermediate portion 46 of the inner trench 40B is defined as a range extending by a predetermined distance in the longitudinal direction from a middle point 47 in the longitudinal direction of the inner trench 40B. The predetermined distance may be the same as the trench width measured along the lateral direction (in this example, the x direction) of the inner trench 40B. Hereinafter, the longitudinal side wall 44 of the inner trench 40B refers to the long side wall 44 in the intermediate portion 46 of the inner trench 40B. On the other hand, the longitudinal side wall 44 of the end trench 40A refers to the longitudinal side wall 44 at an arbitrary position in the longitudinal direction of the end trench 40A.

As shown in FIG. 4, the thickness of the gate insulating film 34 covering the end side wall 42 of the inner trench 40B is defined as “W1”. Although not shown, the thickness of the gate insulating film 34 covering the end side wall 42 of the end trench 40A is also approximately “W1”. As shown in FIG. 3, the thickness of the gate insulating film 34 covering the longitudinal side wall 44 of the end trench 40A is defined as “W2”, and the thickness of the gate insulating film 34 covering the longitudinal side wall 44 of the inner trench 40B is defined as “W3”. In the semiconductor device 1, the thicknesses W1, W2 and W3 satisfy relationships of W1>W3 and W2>W3.

In the semiconductor device 1, the gate insulating films 34 have a relatively large thickness (that is, the thickness W1) on the end side walls 42 of the end trenches 40A and the end side walls 42 of the inner trenches 40B, which have a relatively large surface roughness. Similarly, the gate insulating film 34 have a relatively large thickness (that is, the thickness W2) on the longitudinal side walls 44 of the end trenches 40A. On the other hand, in the semiconductor device 1, the gate insulating films 34 have a relatively small thickness (that is, the thickness W3) on the longitudinal side walls 44 of the inner trenches 40B, which have a relatively small surface roughness. There is a possibility that the withstand voltage and reliability of the gate insulating film 34 of the trench gate 30 are deteriorated on the side wall having a large surface roughness among the side walls of the trenches 40. In the semiconductor device 1, since the gate insulating film 34 of the trench gate 30 corresponding to the side wall having a large surface roughness among the side walls of the trench 40 is formed thick, the deterioration of the withstand voltage and reliability of the gate insulating film 34 is suppressed.

### (Method for Manufacturing Semiconductor Device of First Embodiment)

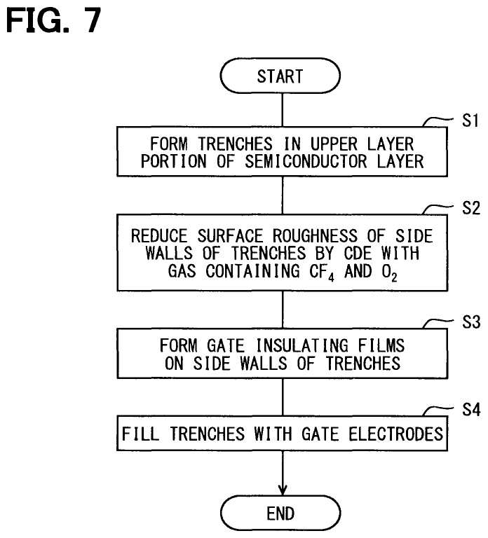

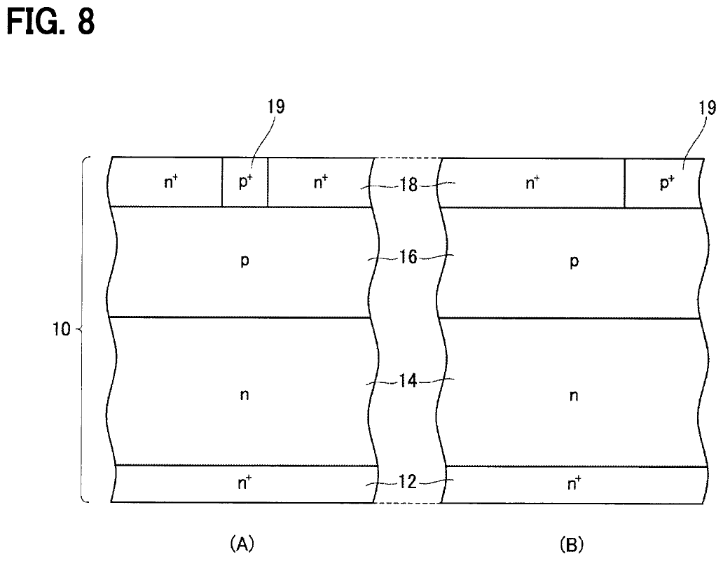

Next, a trench gate forming process in a manufacturing method of the semiconductor device 1 will be described with reference to FIGS. 7 to 11. FIG. 7 shows a manufacturing flow, and FIGS. 8 to 11 schematically show cross-sectional views of main parts of the semiconductor device 1 during the respective processes. In FIGS. 8 to 11, section (A) corresponds to a cross-sectional view of the part taken along line III-III of FIG. 1, and section (B) corresponds to a cross-sectional view of the part taken along line IV-IV of FIG. 1. For the other processes, known techniques can be employed for manufacturing the semiconductor device 1.

First, as shown in FIG. 8, the drain region 12, which is an n⁺-type silicon carbide substrate, is prepared. Next, although not particularly limited, an n-type epitaxial layer of silicon carbide is grown from the surface of the drain region 12 using, for example, an epitaxial growth technique to thereby form the semiconductor layer 10. Next, p-type impurity ions and n-type impurity ions are implanted into the upper layer portion of the semiconductor layer 10 using an ion implantation technique to thereby form the body region 16, the source region 18, and the body contact region 19.

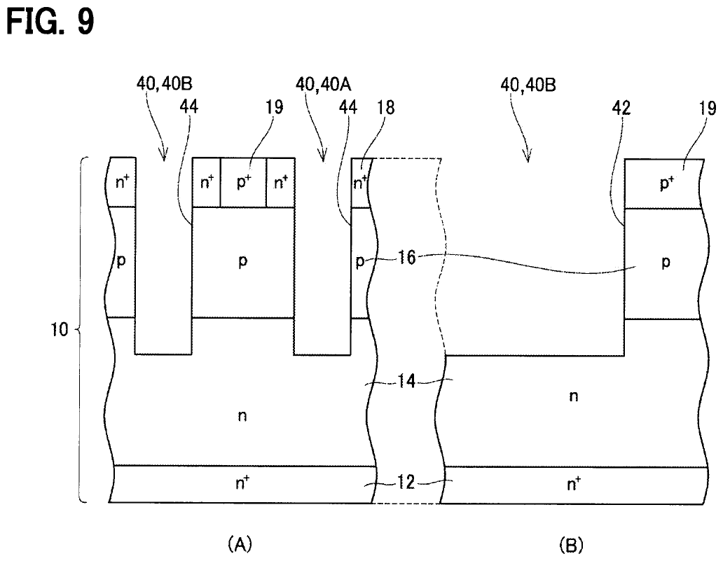

Next, as shown in FIG. 9, the trenches 40 are formed in the upper layer portion of the semiconductor layer 10 using a dry etching technique, corresponding to S1 in FIG. 7. In this trench forming process, the unevenness is formed on the side walls of the trench 40. In particular, the end side walls 42 of the end trenches 40A and the inner trenches 40B are located at the outermost end of the region where the trenches 40 are formed, and there are no trenches 40 outside the outermost end. Therefore, since the surface area per unit of the end side walls 42 of the end trenches 40A and the inner trenches 40B is relatively small, the amount of etching gas supplied per unit increases, and thus the unevenness is formed relatively large. Similarly, the longitudinal side walls 44 of the end trenches 40A also have a relatively small surface area per unit, and thus the unevenness is formed relatively large. On the other hand, the longitudinal side walls 44 of the intermediate portion of the inner trench 40B (that is, the intermediate portion 46 in FIG. 1) are further from from the outermost end of the region in which the trenches 40 are formed, and have a relatively large surface area per unit. Therefore, the unevenness is not formed relatively large.

Next, the unevenness formed on the side walls of the trenches 40 is flattened by a chemical dry etching (CDE) technique using gas containing CF₄ and O₂, so as to reduce the surface roughness of the side walls of the trenches 40, corresponding to S2 in FIG. 7. This flattening process is not performed until the unevenness of all the side walls of the trenches 40 is substantially flat. In other words, the flattening process is terminated before all the side walls of the trenches 40 becomes substantially flat. As shown in FIGS. 5 and 6, the flattening process is terminated in a state where the unevenness remain on the end side walls 42 of the end trenches 40A and the inner trenches 40B and the longitudinal side walls 44 of the end trenches 40A as well as the surface roughness of the end side walls 42 of the end trenches 40A and the inner trenches 40B and the longitudinal side walls 44 of the end trenches 40A is kept to be larger than the surface roughness of the longitudinal side walls 44 of the inner trenches 40B. For example, when the flattening process is continued until the surface roughness of the end side walls 42 of the end trenches 40A and the inner trenches 40B and the surface roughness of the longitudinal side walls 44 of the end trenches 40A become equal to the surface roughness of the longitudinal side walls 44 of the inner trenches 40B, there is a problem that the etching amount increases, resulting in the increase in width of the trenches 40 and the decrease in distance between the adjacent trenches 40. In the manufacturing method of the present embodiment, the distance between the adjacent trenches 40 can be secured by allowing the unevenness of the end side walls 42 of the end trenches 40A and the inner trenches 40B and the longitudinal side walls 44 of the end trenches 40A.

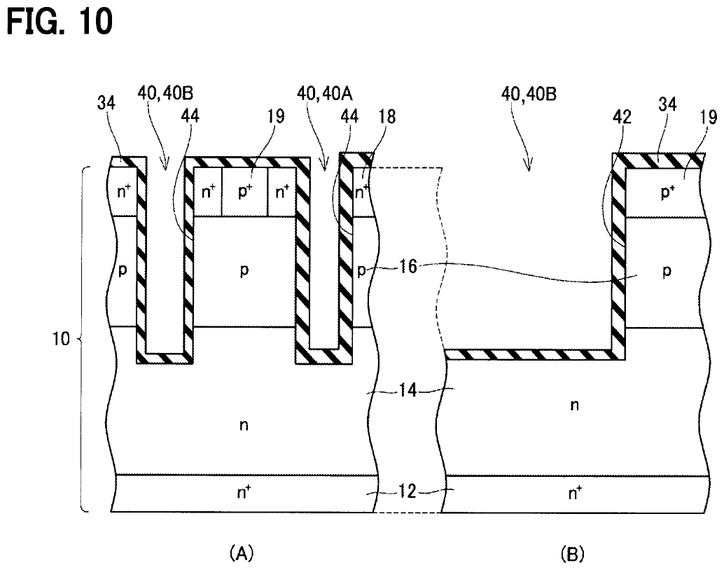

Next, as shown in FIG. 10, the gate insulating film 34 is formed on the side walls of the trenches 40 by using a low pressure chemical vapor deposition (CVD) technique, corresponding to S3 in FIG. 7. Since the surface area per unit of the end side walls 42 of the end trenches 40A and the inner trenches 40B is relatively small, the amount of the source gas supplied per unit is large, and the gate insulating film 34 deposited thereon have a relatively large thickness. Similarly, since the longitudinal side walls 44 of the end trenches 40A also have a relatively small surface area per unit, the gate insulating film 34 deposited thereon have a relatively large thickness. On the other hand, since the longitudinal side walls 44 of the inner trenches 40B have a relatively large surface area per unit, the gate insulating film 34 deposited thereon have a relatively small thickness. As described above, in the trench gate forming process, the thickness of the gate insulating film 34 formed on the side walls having a relatively large surface roughness, among the side walls of the trenches 40, can be relatively increased. That is, the larger the surface roughness of the side walls of the trenches 40, the larger the thickness of the gate insulating film 34 formed thereon is.

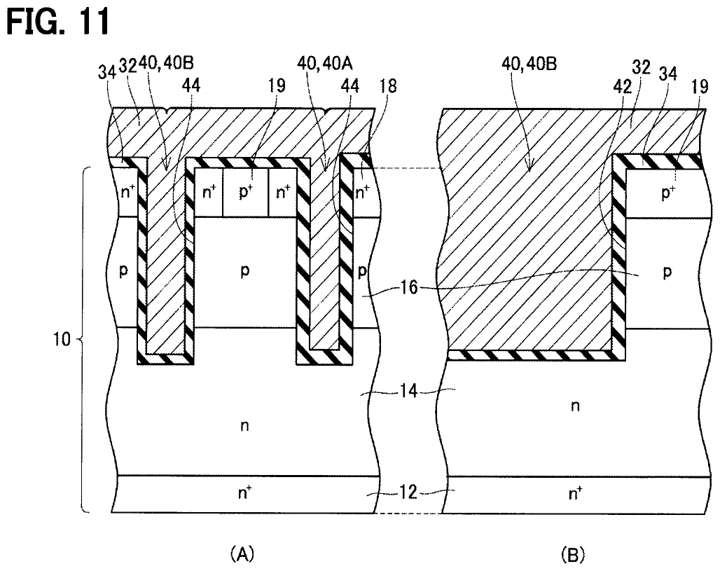

Next, as shown in FIG. 11, the gate electrode 32 is filled in the trench 40 by using the CVD technique, corresponding to S4 in FIG. 7. Thereafter, the gate electrode 32 and the gate insulating film 34 deposited on the upper surface of the semiconductor layer 10 are removed. Thus, the trench gates 30 are formed.

In the manufacturing method described above, the flattening process is terminated in a state where the unevenness having a relatively large surface roughness remain on the end side walls 42 of the end trenches 40A and the inner trenches 40B and the longitudinal side walls 44 of the end trenches 40A. In the subsequent trench gate forming process, the gate insulating film 34 is formed selectively so that the gate insulating film 34 having a larger thickness is deposited on the side wall having the larger surface roughness than that on the side wall having the smaller surface roughness. That is, the thickness of the gate insulating film 34 is increased on the side wall having larger surface roughness than on the side wall having smaller surface roughness. Therefore, in the semiconductor device manufactured by the above manufacturing method, deterioration of the withstand voltage and reliability of the gate insulating film 34 is suppressed. In other words, the above manufacturing method can produce the semiconductor device in which deterioration of the withstand voltage and reliability of the gate insulating film 34 is suppressed while shortening the flattening process in time and reducing the etching amount. Therefore, it is not necessary to secure a large distance between the adjacent trenches 40 in consideration of the etching amount. According to the above manufacturing method, it is possible to manufacture a semiconductor device having a miniaturized trench pit.

### Second Embodiment

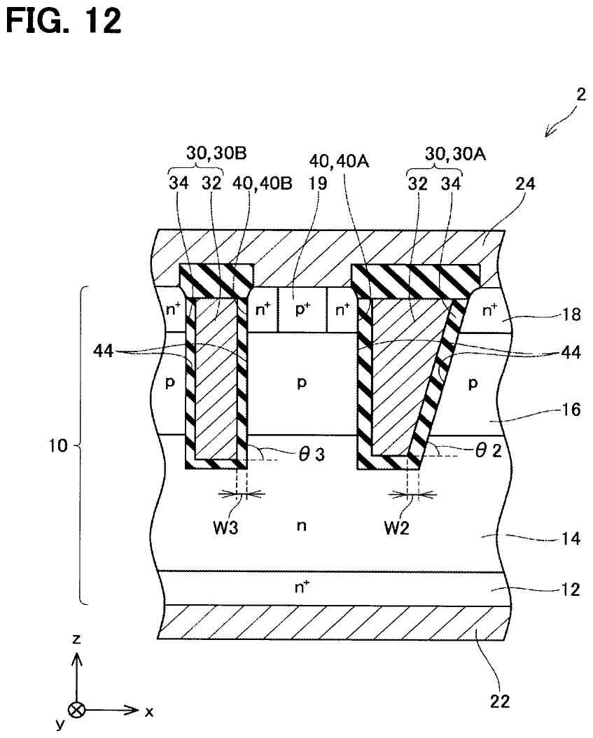

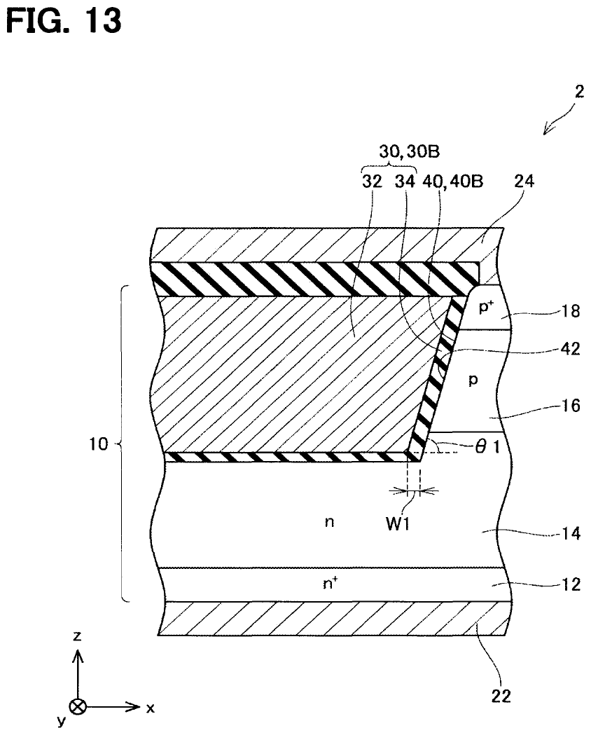

FIGS. 12 and 13 show a semiconductor device 2 according to a second embodiment. As shown in FIG. 13, the end side wall 42 of the inner trench 40B has an inclination angle of “θ1”. Although not shown, the inclination angle of the end side wall 42 of the end trench 40A is also substantially “θ1”. Further, as shown in FIG. 12, of the pair of longitudinal side walls 44 of each end trench 40A, the outer longitudinal side wall 44, which is on the outer side in the repeating direction (in this example, the x direction), has an inclination angle of “θ2”. Further, the longitudinal side wall 44 of the inner trench 40B has an inclination angle of “θ3”. In the semiconductor device 2, these inclination angles θ1, θ2 and θ3 satisfy the relationships of θ1<θ3 and θ2<θ3. Here, each inclination angle is an external angle defined between a plane parallel to the upper surface of the semiconductor layer 10 (in this example, the xy plane) and the corresponding side wall of the trench 40.

On the side wall having a relatively small inclination angle, the film thickness of the gate insulating film 34 becomes relatively large due to an increase in coverage in the gate insulating film forming process. In the present embodiment, the gate insulating film 34 have the same thickness relationships among the thicknesses W1, W2, and W3 as that of the semiconductor device 1 of the first embodiment. Therefore, in the semiconductor device 2, the thickness of the gate insulating film 34 is relatively large on the end side walls 42 of the end trenches 40A and the inner trenches 40B and the longitudinal side walls 44 of the end trenches 40A. As a result, in the semiconductor device 2, since the gate insulating film 34 of the trench gate 30 is formed to be thick on the side wall having the larger surface roughness, the degradation of the withstand voltage and reliability of the gate insulating film 34 can be suppressed.

### (Method of Manufacturing Semiconductor Device of Second Embodiment)

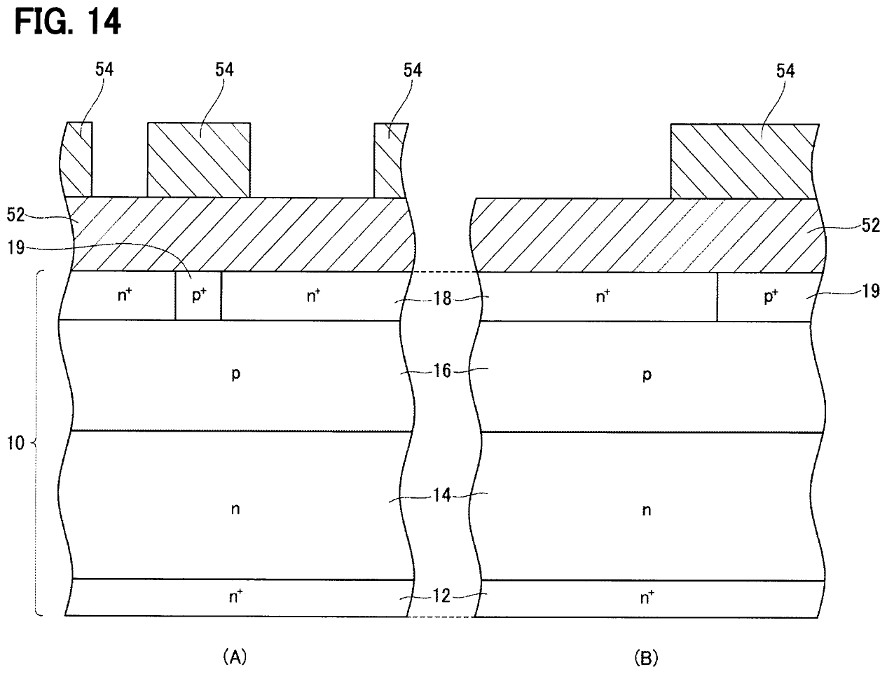

Next, a trench gate forming process in the manufacturing method of the semiconductor device 2 will be described with reference to FIGS. 14 to 17. In FIGS. 14 to 17, section (A) corresponds to a part of the semiconductor device 2 taken along a line III-III of FIG. 1, and section (B) corresponds to a part of the semiconductor device 2 taken along a line IV-IV of FIG. 1.

First, the process until the semiconductor layer 10 is prepared is the same as that in the manufacturing method of the semiconductor device 1 of the first embodiment shown in FIG. 8. Next, as shown in FIG. 14, a mask 52 is formed on the upper surface of the semiconductor layer 10 using a CVD technique. The mask 52 is not particularly limited, but may be, for example, made of silicon oxide. Next, a resist 54 is patterned on the mask 52 using a photolithography technique. The resist 54 has an opening corresponding to a trench formation region where the trench 40 for the trench gate 30 is to be formed.

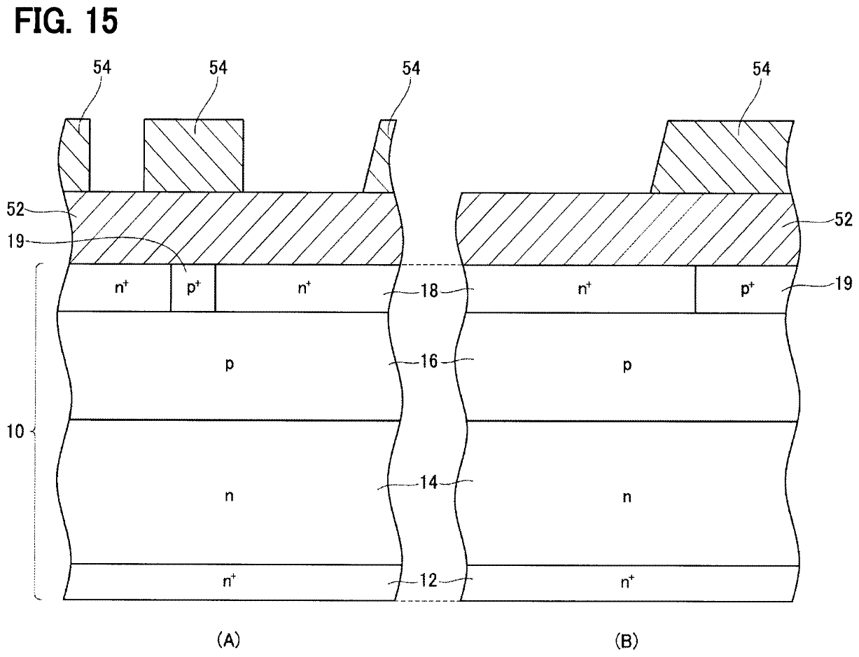

Next, as shown in FIG. 15, the resist 54 is shrunk using a heat treatment technique. The shrinkage amount of the resist 54 increases as the surface area increases. Therefore, among the side surfaces defining the openings of the resist 54, the side surface adjacent to the resist 54 having a larger surface area is inclined larger. In this example, the side surfaces of the openings of the resist 54 corresponding to the end side walls 42 of the end trenches 40A and the inner trenches 40B and the longitudinal side walls 44 of the end trenches 40A are largely inclined.

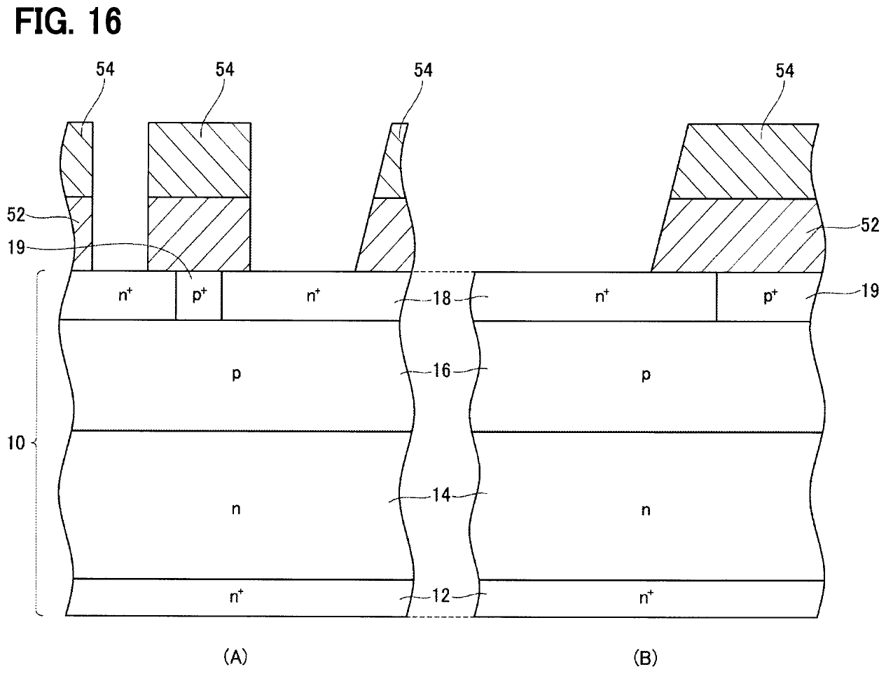

Next, as shown in FIG. 16, a part of the mask 52 exposed from the opening of the resist 54 is etched using a dry etching technique to thereby form an opening in the mask 52. The opening formed in the mask 52 takes over the shape of the opening formed in the resist 54.

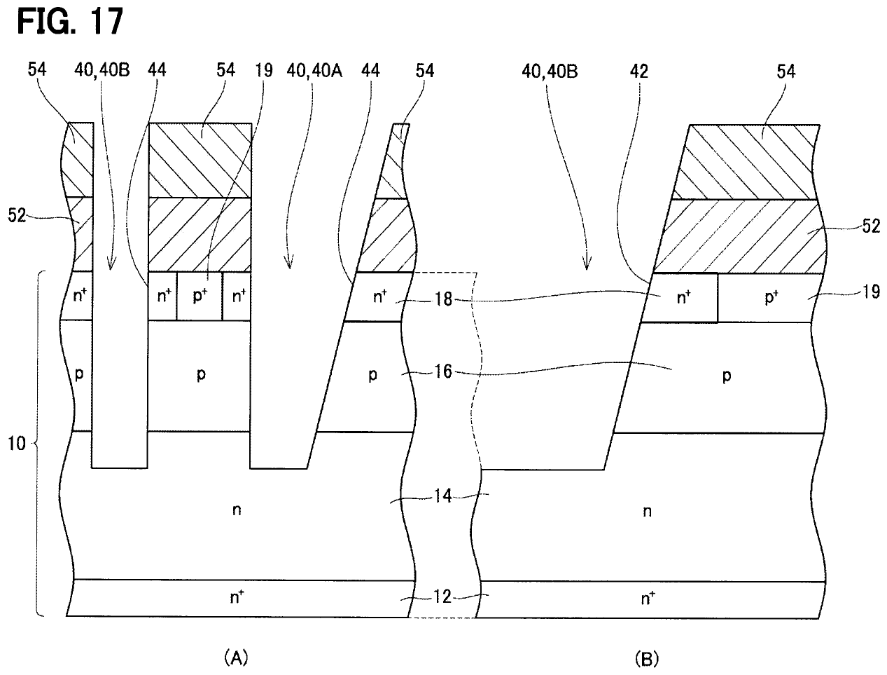

Next, as shown in FIG. 17, the upper layer portion of the semiconductor layer 10 exposed from the opening of the mask 52 is etched using a dry etching technique to thereby form the trenches 40 in the upper layer portion of the semiconductor layer 10. The trench 40 formed in the upper layer portion of the semiconductor layer 10 takes over the shape of the opening formed in the mask 52. This trench forming process corresponds to the trench forming process in the manufacturing method of the semiconductor device 1 of the first embodiment as in S1 in FIG. 7. The subsequent processes are similar to those in the manufacturing method of the semiconductor device 1 according to the first embodiment. In this way, the trench gates 30 of the semiconductor device 2 can be formed. As described above, since the inclination angles of the end side walls 42 of the end trench 40A and the inner trench 40B and the longitudinal side walls 44 of the end trenches 40A are relatively small, the thickness of the gate insulating films 34 covering the end side walls 42 of the end trench 40A and the inner trench 40B and the longitudinal side walls 44 of the end trench 40A becomes relatively large due to an increase in coverage in the gate insulating film forming process.

### Third Embodiment

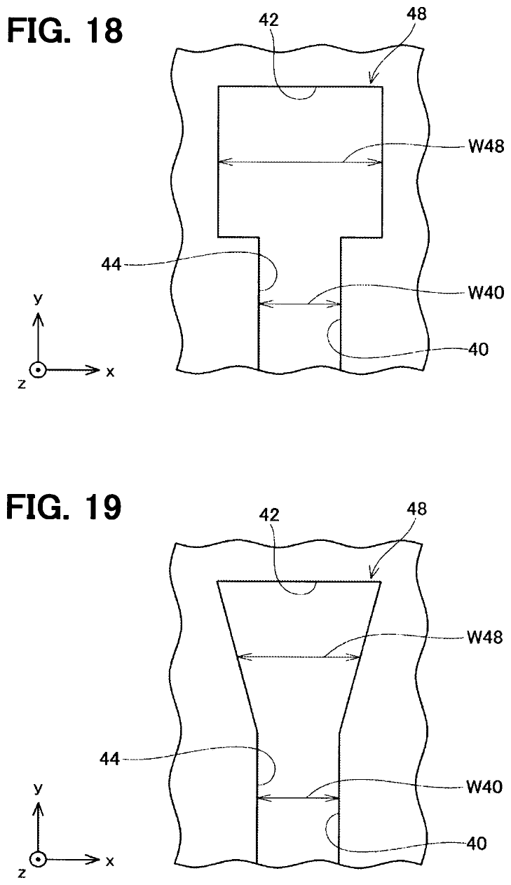

A third embodiment of the present disclosure will be described with reference to FIGS. 18 to 20. In order to selectively increase the thickness of the gate insulating film 34 at both end portions in the longitudinal direction of the trench gate 30, the aspect ratio of the end portions in the longitudinal direction of the trench 40 may be increased. When the aspect ratio of the trench 40 is large, the film thickness of the gate insulating film 34 increases due to an increase in coverage in the gate insulating film forming process.

FIG. 18 shows an example in which the trench width W48 at both end portions 48 in the longitudinal direction of the trench 40 is formed to be large. In this case, both the end portions 48 in the longitudinal direction of the trench 40 are formed into a rectangular shape in the plan view. An intermediate portion of the trench 40 other than the end portions 48 have the constant width W40 between the end portions 48. Here, the end portion 48 of the trench 40 is defined in a predetermined range that begins from the end side wall 42 by a predetermined distance along the longitudinal direction. The predetermined distance is equal to or greater than the width W40 of the intermediate portion of the trench 40, and may be ten times or less, eight times or less, or five times or less the width W40 of the intermediate portion of the trench 40. The trench width is a dimension measured along a direction orthogonal to the longitudinal direction of the trench 40. As described above, both the end portions 48 of the trench 40 are formed to have a larger aspect ratio relative to the intermediate portion of the trench 40. As a result, the gate insulating film 34 is formed to have a large film thickness in the end portion 48 due to an increase in coverage in the gate insulating film forming process.

FIG. 19 shows an example in which the trench width W48 at both the end portions 48 of the trench 40 in the longitudinal direction is formed to be large, so that the end portions 48 have a trapezoidal shape in the plan view. The trench width W48 of the end portions 48 of the trench 40 continuously increases outward along the longitudinal direction of the trench 40. Also in this example, the aspect ratio of the end portions 48 is large in the trench 40. As a result, the thickness of the gate insulating film 34 is formed to be large due to an increase in coverage in the gate insulating film forming process.

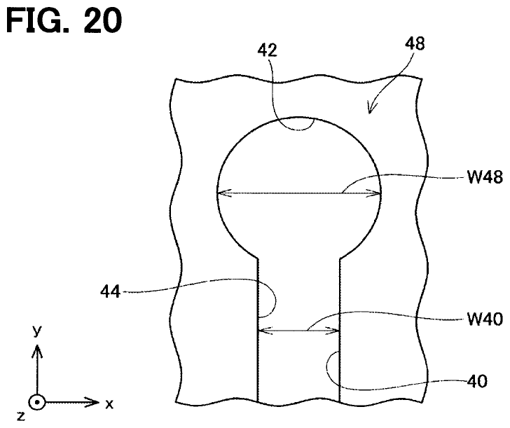

FIG. 20 shows an example in which the trench width W48 at the end portions 48 of the trench 40 in the longitudinal direction is larger than the width W40 of the intermediate portion of the trench 40. In this case, the end portions 48 are formed into a circular shape in the plan view. Also in this example, the aspect ratio of the end portions 48 is large, relative to the intermediate portion of the trench 40. As a result, the gate insulating film 34 is formed to have the larger film thickness at the end portions 48 due to an increase in coverage in the gate insulating film forming process.

The examples of FIGS. 18 to 20 can be easily manufactured only by changing the patterning of the mask corresponding to the shapes of both the end portions 48 of the trench 40.

The features of the techniques disclosed in the present disclosure will be independent technical elements and exhibit technical usefulness alone or in various combinations, and are not limited to the combinations described herein.

While only the selected exemplary embodiments and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiments and examples according to the present disclosure is provided for illustration only, and not for the purpose of limiting the disclosure as defined by the appended claims and their equivalents.

What is claimed is:

1. A semiconductor device comprising:
a semiconductor layer formed with a plurality of trenches in a surface layer portion; and
a plurality of trench gates correspondingly provided in the plurality of trenches of the semiconductor layer, wherein
each of the plurality of trenches extends at least in a first direction in a plan view of the semiconductor layer,
the plurality of trenches are arranged apart from each other in a second direction orthogonal to the first direction in the plan view of the semiconductor layer,
each of the plurality of trenches has a pair of end side walls at ends in the first direction and a pair of longitudinal side walls extending between the pair of end side walls,
the plurality of trenches include a pair of end trenches located at opposite ends in the second direction and an inner trench located between the pair of end trenches in the second direction,
at least one of the end side walls of the inner trench has a surface roughness larger than a surface roughness of at least one of intermediate portions of the longitudinal side walls of the inner trench, the intermediate portions being at an intermediate position of the inner trench in the first direction, and
the gate insulating film disposed in the inner trench has a larger thickness on the at least one of the end side walls than on the at least one of the intermediate portions of the longitudinal side walls.

2. The semiconductor device according to claim 1, wherein
the at least one of the end side walls of the inner trench has a smaller inclination angle than that of the at least one of the intermediate portions of the longitudinal side walls, the inclination angle being defined relative to the surface of the semiconductor layer.

3. The semiconductor device according to claim 1, wherein
at least one of the trenches has a larger width at opposite ends in the first direction than at the intermediate position between the opposite ends, the width being defined in the second direction.

4. The semiconductor device according to claim 1, wherein
at least one of the end trenches has an outer longitudinal side wall as one of the pair of longitudinal side walls on an outer side in the second direction,
the outer longitudinal side wall has a surface roughness larger than the surface roughness of the at least one of the intermediate portions of the longitudinal side walls of the inner trench, and
the gate insulating film disposed in the at least one of the end trenches and covering the outer longitudinal side wall has a thickness larger than that of the gate insulating film on the at least one of the intermediate portions of the longitudinal side walls of the inner trench.

5. The semiconductor device according to claim 1, wherein
the semiconductor layer is made of silicon carbide.

6. A manufacturing method of a semiconductor device, the method comprising:
forming a plurality of trenches in an upper layer portion of a semiconductor layer; and
forming a plurality of trench gates correspondingly in the plurality of trenches of the semiconductor layer, wherein
in the forming of the plurality of trenches,
each of the plurality of trenches is formed to extend at least in a first direction in a plan view of the semiconductor layer, and to have a pair of end side walls at opposite ends in the first direction and a pair of longitudinal side walls extending between the end side walls,
the plurality of trenches are formed to be arranged spaced apart from each other in a second direction orthogonal to the first direction in the plan view of the semiconductor layer, and to include a pair of end trenches located at opposite ends in the second direction and an inner trench located between the pair of end trenches in the second direction, and
the forming of the plurality of trench gates includes forming a gate insulating film in the inner trench so that a thickness of the gate insulating film on at least one of the end side walls of the inner trench is larger than a thickness of the gate insulating film on at least one of intermediate portions of the longitudinal side walls of the inner trench, the intermediate portions being at an intermediate position of the inner trench in the first direction, in a state where the at least one of the end side walls of the inner trench has a surface roughness larger than a surface roughness of the at least one of the intermediate portions of the longitudinal side walls of the inner trench.

7. The manufacturing method according to claim 6, wherein
the forming of the plurality of trenches includes forming the inner trench so that the at least one of the end side walls has an inclination angle smaller than that of the at least one of the intermediate portions of the longitudinal side walls, the inclination angle being defined relative to a surface of the semiconductor layer.

8. The manufacturing method according to claim 6, wherein
the forming of the plurality of trenches includes forming at least one of the plurality of trenches so that a width at opposite ends in the first direction is larger than a width at the intermediate position between the opposite ends, the width being defined in the second direction.

9. The manufacturing method according to claim 6, wherein
the forming of the plurality of trench gates includes forming a gate insulating film in at least one of the end trenches so that a thickness of the gate insulating film on an outer longitudinal side wall of the at least one of the end trenches is larger than the thickness of the gate insulating film on the at least one of the intermediate portions of the longitudinal side walls of the inner trench, the outer longitudinal side wall being one of the pair of longitudinal side walls of the at least one of the end trenches and on an outer side in the second direction, in a state where the outer longitudinal side wall of the at least one of the end trenches has a surface roughness larger than that of the at least one of the intermediate portions of the longitudinal side walls of the inner trench.

10. The manufacturing method according to claim 6, wherein
the semiconductor layer is made of silicon carbide.
